(19) United States
(12) Patent Application Publication
(10) Pub. No.: US 2025/0373146 A1
(43) Pub. Date: Dec. 4, 2025

(54) CONVERTER AND A METHOD FOR OPERATING A CONVERTER

(71) Applicant: Siemens Energy Global GmbH & Co. KG, München (DE)

(72) Inventors: Christoph Armschat, Erlangen (DE); Herbert Gambach, Uttenreuth (DE); Jörg Kaytzuck, Heroldsberg (DE); Torsten Stoltze, Herzogenaurach (DE); Andreas Hoffmann, Dresden (DE)

(21) Appl. No.: 19/225,077

(22) Filed: Jun. 2, 2025

(30) Foreign Application Priority Data
May 31, 2024 (EP) 24179274.6

(51) Int. Cl. H02M 1/12; H02M 1/00; H02M 7/217; H02M 7/219; H02M 7/25

(52) U.S. Cl. CPC H02M 1/12; H02M 1/0009; H02M 7/2173; H02M 7/219; H02M 7/25

(57) ABSTRACT

A converter includes at least one switching module with an energy store and semiconductor switches to allow and block current flow through the energy store. A method of operating the converter includes the steps of measuring a voltage present across the energy store and measuring a current flowing through the energy store. A capacitance of the energy store is determined by minimizing an objective function of the voltage, the current, the capacitance and a time over the minimization parameters capacitance and time. There is also described a converter with a converter control that is configured to operate the converter in accordance with the method.

### CROSS-REFERENCE TO RELATED APPLICATION

This application claims the priority, under 35 U.S.C. § 119, of European Patent Application EP 24179274.6, filed May 31, 2024; the prior application is herewith incorporated by reference in its entirety.

### FIELD AND BACKGROUND OF THE INVENTION

The present invention relates to a method for operating a converter, the converter comprising a switching module, wherein the switching module comprises an energy store and semiconductor switches to alternatively allow or block current flow through the energy store. The method comprises the steps of measuring a voltage present across the energy store, and measuring current flowing through the energy store.

In most of the existing converter systems it is not possible to continuously monitor the energy store devices during operation. Failures of energy stores therefore often occur as a surprise.

An exact measurement of the capacity of a converter capacitor is usually only possible when the converter is out of operation, using a capacitance measurement bridge. When determining the capacitance from voltage and current measurement during operation, several effects reducing the accuracy of the capacitance determination must be considered, including measurement offsets, disturbances and electromagnetic interference.

European Patent EP 2 100 365 B1 discloses a prior art method in which a capacitor voltage across a converter capacitor and a phase module current is measured to determine a capacitance of the capacitor.

### SUMMARY OF THE INVENTION

It is an object of the invention to provide a converter and an operating method which overcome a variety of the disadvantages associated with the heretofore-known devices and methods of this general type and which provides for a method that allows an effective capacitance monitoring of a converter during operation.

With the above and other objects in view there is provided, in accordance with the invention, a method for operating a converter, wherein the converter has at least one switching module with an energy store (i.e., energy storage device) and semiconductor switches to selectively allow or block a current flow through the energy store. The method includes the following method steps:
measuring a voltage across the energy store;
measuring a current flowing through the energy store; and
determining a capacitance of the energy store by minimizing an objective function of the voltage, the current, the capacitance and a time over the minimization parameters capacitance and time.

In other words, a centrally important step of the novel method is a step of determining a capacitance of the energy storage device by minimizing an objective function of the voltage, the current, the capacitance and a time over the minimization parameters capacitance and time. That is, determining the capacitance is done via finding values of capacitance and time so that the objective function that depends on the variables voltage (across the energy store), current (through the energy store), capacitance, and time, reaches a minimum value. So, instead of using a forward computation e.g., by means of a given formula, the determination of the capacitance is performed as an optimization problem. In addition, instead of using capacitance as the only minimization parameter, the method of the present invention requires to also use time (or time shift) as another minimization parameter.

The advantage of including time as an additional minimization parameter is that it allows to minimize an error that originates from measurement time shifts. In general, measurement signals from current and voltage measurements have temporal shifts (jitter). According to our investigations, these temporal shifts cause significant errors in determining capacitances. By including time as another computational parameter, these effects can be significantly reduced.

According to an embodiment of the invention, the objective function depends on a time integral of the current. In particular, the following equation generally holds for capacitance:

$$Uc ( t ) - U 0 = 1 / C * time integral [ i ( t ’ ) dt ’ ] ,$$

where Uc is a voltage across the energy store at time t, U0 is an initial voltage, C is the capacitance and i(t′) is the current flowing through the energy store at a time t′. Thus, there is a correspondence between the capacitance and the time integral of the current. In practice, the current can be integrated in accordance with known numerical integration methods (e.g., using the trapezoidal rule).

The objective function f to be minimized preferably is given by

$$f = ( ( Uc ( t ) - U 0 ) / [ 1 / C * int\_s ( i ( s ) ds ) ] - 1 ) \hat{} 2 ,$$

where int_s denotes a time integral with s as time parameter. The actual capacitance Cact can be determined via f(Cact)=min f. The capacitance determination by way of a function optimization (minimization) has the advantage of a high accuracy even in the presence of noisy measurement signals. It will be understood that the function f is by definition a non-negative function with a minimum at f=0.

According to an embodiment, the minimization parameter values lie within predefined parameter limits. A lower limit for the capacitance can for example be set to 50% of a nominal capacitance, an upper limit to 120% of the nominal capacitance. The time shift limits may preferably be: zero for the lower limit and 100 microseconds for the upper limit. By setting proper limits implausible function minima can be avoided.

In a preferred embodiment, the measured voltage and/or current values are smoothed before determining the capacitance. Additionally, outlier values can be detected and removed from the data. In this way single measurement errors (e.g., through disturbances) can be avoided.

The method can further comprise a step of identifying an offset in the measured current before determining the capacitance. The measured current usually shows an offset that has a negative influence on the determination of the capacitance. To detect and remove the offset, the current signal can be cut into segments. The measurement data originating from different segments can then be compared. In particular, it is advantageous to compare measurement segments from different switching modules in one arm of a modular multilevel converter.

Preferably the method further comprises the step of detecting an abnormal capacitance value. If an abnormal value of the capacitance is detected, a corresponding anomaly information can be provided to a monitoring system. The detection of abnormal capacitance can be done using the following approaches (alone or in combination).

The value of capacitance (of a given energy store) at a given time is compared with capacitance values of other energy stores. For example, in a modular multilevel converter having converter arms, the capacitance values of a given energy store are compared with capacitance values of other energy stores of the same converter arm. Since all energy stores of the same converter arm are subject to similar environmental conditions (like temperature), the comparison allows to minimize the impact of temperature and systematical measurement errors.

To detect an abnormal value, the capacitance value can be normalized, i.e., divided by a reference value recorded after commissioning (“starting value of capacitance”) and then compared with a predefined threshold. This allows to avoid an error that originates from the fact that different energy stores may have different nominal maximum capacitances.

Capacitance values generally show long-term changes (also called a capacitance value drift). When detecting abnormal behavior of an energy store, this long-term behavior may be considered. To consider the value drift, capacitance value changes over time (instead of the capacitance values themselves) may be analyzed over a long period of time (weeks or months). As an example, an indicator of an abnormal behavior of an energy store is a decrease of the capacitance value (of a given energy store) that is faster than a predefined decrease threshold or, alternatively, faster than an average capacitance value decrease of other energy stores. The amount of drift can for example be specified in a percentage per month.

To avoid sending a message to the monitoring system each time an anomaly is found, a threshold value for a number of consecutive anomalies can be specified that must be exceeded before the message is sent.

Preferably some or all method steps described above are repeated several times (e.g., thrice) a day. A more frequent repetition of the capacitance determination allows for a more precise and reliable monitoring of the converter.

Under certain conditions the calculation of a low capacity can also result from a faulty voltage measurement that is too high. In order to distinguish capacitor degrading from voltage measurement errors, the discharging process of the energy store of a switching module with the calculated low capacity is compared with the discharging process of other switching modules in the same converter arm under comparable load conditions. If the voltage in the conspicuous switching module (with the calculated low capacity) drops significantly faster during discharging than in other submodules, a possible error in the voltage measurement can be ruled out, and it is then certain that the low capacity of the capacitor is the cause.

With the above and other objects in view there is also provided, in accordance with the invention, a converter for converting electrical power. This kind of converter may for example be used for HVDC (AC/DC or DC/DC converters) and FACTS applications. Usually, such converters comprise a plurality of semiconductor switches and at least one energy store or storage device (e.g., a capacitor).

According to the invention, the converter comprises a converter control that is configured to operate the converter in accordance with the method described above.

According to an embodiment the converter is a modular multilevel converter having a series of switching modules each comprising an energy store (e.g., a capacitor), wherein the converter control is configured to determine a capacitance of some, preferably of all energy stores. A modular multilevel converter (MMC) comprises a series of switching modules in each of the converter arms. Each of the switching modules comprises switch-off type semiconductor switches, like e.g., IGBT, IGCT, MOSFET (including wide-gap semiconductor-based switches) and an energy store, such as, e.g., a capacitor. Every switching module can be individually controlled to provide certain module voltage at its terminals (e.g., the energy store/capacitor voltage or a zero voltage in case of a half-bridge module, or the energy store/capacitor voltage, a negative energy store/capacitor voltage or a zero voltage in case of a full-bridge module).

Other features which are considered as characteristic for the invention are set forth in the appended claims.

Although the invention is illustrated and described herein as embodied in a converter and a method for operating a converter, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 shows a schematic view of a converter according to an embodiment of the invention;

FIG. 2 shows a schematic view of a converter according to another embodiment of the invention;

FIG. 3 shows a diagram of an exemplary switching module for a converter according to the invention; and

FIG. 4 is a flow diagram of an embodiment of the method according to the invention.

### DETAILED DESCRIPTION OF THE INVENTION

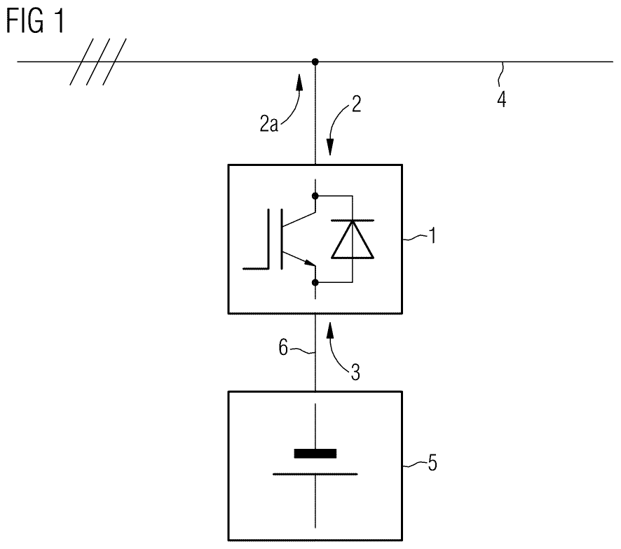

Referring now to the figures of the drawing in detail and first, in particular, to FIG. 1 thereof, there is shown a converter 1 with an AC side 2 and a DC side 3. The converter 1 is a voltage source converter. The AC side 2 of the converter 1 is connected to an AC grid 4 at a connecting node 2a. The DC side 3 of the converter is connected to an electrical energy storage device 5, referred to as an energy store 5, via a DC link 6. The converter 1 is designed to stabilize the AC grid 4 by exchanging active and reactive power with the AC grid 4.

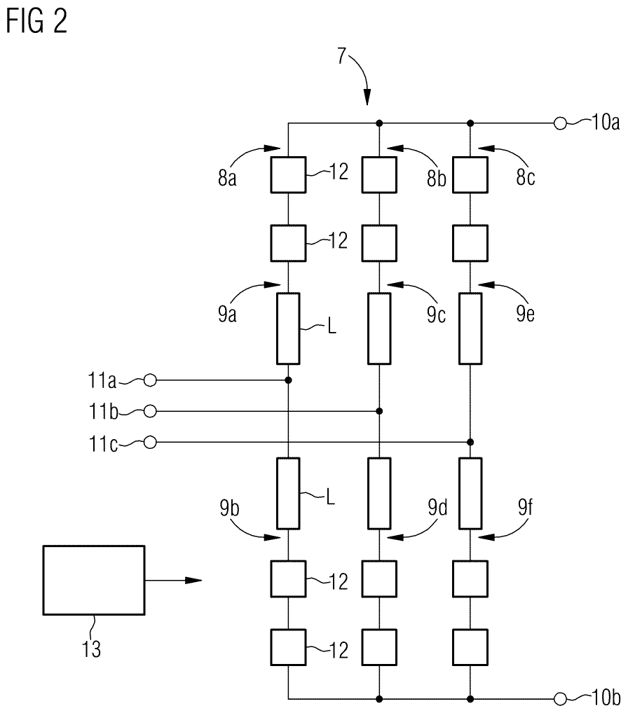

FIG. 2 shows a voltage source converter being a modular multilevel converter (MMC) 7. The MMC 7 comprises three phase branches 8a, 8b, 8c and six converter arms 9a, 9b, 9c, 9d, 9e, 9f. Every converter arm 9a-f extends between one of the DC poles or terminals 10a,b, constituting a DC side of the converter 7, and one of the AC terminals 11a-c constituting an AC side of the converter 7. Each converter arm 9a-f comprises an arm inductance L and a number of switching modules 12 connected in series. The number of switching modules 12 in every converter arm 9a-f can in general be chosen to best match the needs of a given application (and is not restricted to the illustrated two per arm). The switching modules 12 can for example be so-called half-bridge or full-bridge switching modules (or a combination of both). A proper control of the semiconductor switches of a full-bridge switching module 12 creates a positive, a negative or a zero voltage across its terminals. The converter 7 comprises a converter control 13 for controlling the operation of the converter 7.

The MMC 7 is suitable for grid stabilization applications (as shown in FIG. 1) and for high-voltage direct current energy transmission (HVDC), wherein its DC side is connected to a DC transmission line. Particularly in HVDC applications each of the converter arms can comprise full-bridge switching modules, half-bridge switching modules, other switching module topologies or any combinations thereof.

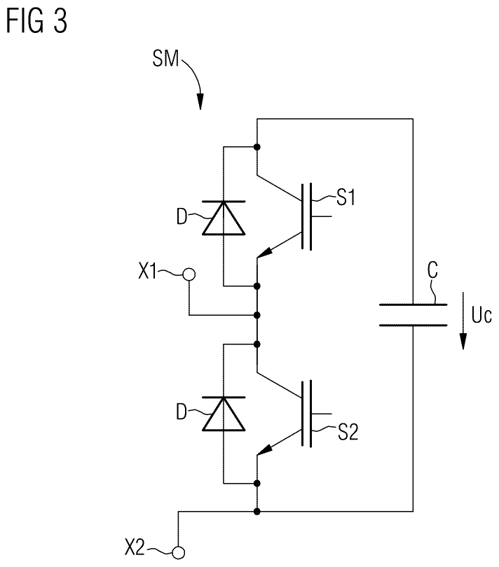

An example of a half-bridge switching module SM is shown in FIG. 3. The switching module SM comprises two terminals X1, X2 to connect, for example, to further, neighboring switching modules. The switching module SM further comprises two semiconductor switches S1, S2 of the turn-off type with antiparallel freewheeling diodes D. An energy storage element (capacitor) C is connected in parallel with the series connection of the semiconductor switches S1,S2. By a proper control of the switches S1, S2, the capacitor C can be bypassed (the converter current flow through the capacitor is blocked), implying a zero voltage at the terminals X1, X2. Alternatively, if a flow of the converter current through the capacitor is allowed, the voltage across the terminals X1, X2 corresponds to the capacitor voltage Uc.

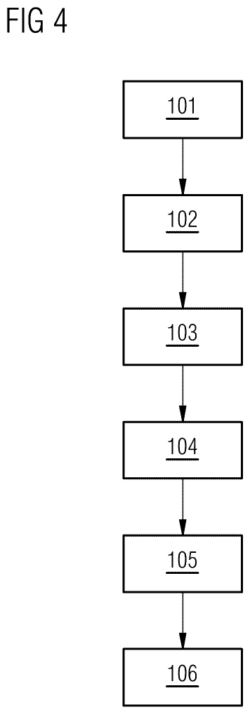

As seen from FIGS. 1 to 3, the converter comprises a plurality of energy stores in the form of capacitors. During the operation of the converter the capacitances of the capacitors are monitored. The monitoring comprises a determination of a capacitance of the converter capacitors. FIG. 4 shows the steps of a method to determine the capacitance of the capacitor.

The steps shown in FIG. 4 show the method applied to one of the energy stores, or energy storage devices. However, the operation of the converter may comprise same method steps applied to some or all its energy stores.

In a first step 101 the voltage across the capacitor and the current flowing through the capacitor are measured and the measured voltage and current values are provided to the converter control for further processing.

In a second step 102 the measured values are further processed, in particular the measured values are smoothed, and a current offset is eliminated from the measured data.

In a third step 103 a capacitance of said energy store is determined by minimizing an objective function of voltage, current, capacitance and time, i.e., using an optimization routine, values of a time variable and a capacitance variable are found, such that the objective function reaches a minimum. There are optimization routines or algorithms known form prior art that are applicable to the present method, like e.g. global optimization, e.g., controlled random search with local mutation, multi-level single-linkage, improved stochastic ranking evolution strategy, local derivative-free optimization, e.g., constrained optimization by linear approximations, local gradient-based optimization, e.g., sequential quadratic programming, or others. In order to use f=((Uc(t)−U0)/[1/C*int_s(i(s)ds)]−1)\hat{ }2 as the objective function, the current i is numerically integrated to obtain int_s(i(s)). Instead of the noted function f any other suitable function can be used, as for example a square root of f. In some applications also f′=∥(Uc(t)−U0)/[1/C*int_s(i(s)ds)]∥_2 can be considered.

In a fourth step 104 an abnormal value of the capacitance is detected. The capacitance value of the capacitor is compared with capacitance values of other capacitors of the same converter arm of the MMC. If the capacitance value of the capacitor is lower than an average of capacitance values of all capacitors of the same converter arm minus a predefined gap value, then the capacitance value is recorded as abnormal. In addition, the capacitance value is compared with past capacitance values of the capacitor: the capacitance value is recorded as abnormal if the capacitance value decreases faster than a predefined decrease threshold.

In a fifth step 105 the determination of the capacitance is repeated after a predefined time (e.g., several hours or days).

In a sixth step 106, if an abnormal capacitance is detected repeatedly (i.e., a predefined number of times), a corresponding notification is provided to a converter monitoring system. With this information a decision can be reached, for instance by a superordinate control or by a human supervisor, to take a maintenance action.

1. A method for operating a converter, the method comprising:
providing the converter with at least one switching module, the switching module having an energy store and semiconductor switches to selectively allow or block a current flow through the energy store;
measuring a voltage across the energy store;
measuring a current flowing through the energy store; and
determining a capacitance of the energy store by minimizing an objective function of the voltage, the current, the capacitance and a time over minimization parameters capacitance and time.

2. The method according to claim 1, wherein the objective function depends on a time integral of the current.

3. The method according to claim 1, wherein the minimization parameters are constrained within predefined parameter limits.

4. The method according to claim 1, which comprises smoothing at least one of the measured voltage or the current values before determining the capacitance.

5. The method according to claim 1, which comprises identifying an offset in the measured current before determining the capacitance.

6. The method according to claim 1, which further comprises a step of detecting an abnormal capacitance value.

7. The method according to claim 6, wherein the step of detecting an abnormal capacitance value considers a long-term capacitance value drift.

8. The method according to claim 1, which comprises repeating the method steps several times a day.

9. A converter for converting electrical power, comprising a converter control configured to operate the converter in accordance with the method according to claim 1.

10. The converter according to claim 9, being a modular multilevel converter having a series of switching modules each comprising an energy store, wherein said converter control is configured to determine a capacitance of all energy stores.
